(19) United States
(12) Patent Application Publication
(10) Pub. No.: US 2004/0174212 A1
(43) Pub. Date: Sep. 9, 2004

(54) Doherty amplifier using adaptive bias control

(75) Inventors: Bumman Kim, Kyungsangbuk-do (KR); Jeonghyeon Cha, Kyungsangbuk-do (KR); Bumjae Shin, Kyungsangbuk-do (KR)

Correspondence Address: BACON & THOMAS, PLLC, 625 SLATERS LANE, FOURTH FLOOR, ALEXANDRIA, VA, 22314

(73) Assignee: POSTECH FOUNDATION, Kyungsangbuk-do (KR)

(21) Appl. No.: 10/724,836

(22) Filed: Dec. 2, 2003

(30) Foreign Application Priority Data
Mar. 8, 2003 (KR) 10-2003-0014556

(51) Int. Cl. H03F 3/68

(52) U.S. Cl. 330/124 R

(57) ABSTRACT

An amplifier circuit using an adaptive bias control comprises an envelope detector for detecting an envelope of an input signal from a coupler, envelope shaping circuits for transforming of the envelope voltage from the envelope detector. The one transformed envelope voltage is applied to a drain bias for the peaking amplifier and the other is add by V_{DC} to be applied to a gate bias for the carrier amplifier. In the Doherty amplifier, the gate voltage of the peaking amplifier and the drain voltage of the peaking amplifier are controlled in accordance with the input signal envelope to maximize efficiency with a desired linearity.

### FIELD OF THE INVENTION

The present invention relates to an amplifier circuit; and, more particularly, to a Doherty amplifier using an adaptive bias control to maximize efficiency while improving its linearity to a desired level.

### BACKGROUND OF THE INVENTION

As is well known in the art, a Doherty amplifier is a high efficiency amplifier capable of performing an input and output impedance matching process. The Doherty amplifier generally uses two amplifiers, a carrier amplifier and a peaking amplifier, and controls a load line impedance of the carrier amplifier by varying, depending on a power level of an input signal, the amount of current provided from the peaking amplifier to the load. To attain such a high efficiency performance over a wide input signal bandwidth, the Doherty amplifier employs a technique where the carrier amplifier and the peaking amplifier are connected in parallel to each other by a quarter-wave transmission line (λ/4 line).

The Doherty amplifier was used in earlier days as an amplitude modulation (AM) transmitter of a broadcasting apparatus using a high-power low-frequency/middle-frequency (LF/MF) vacuum tube. Then, various suggestions have been made to apply the Doherty amplifier to a solid-state high-power transmitter.

In FIG. 1, there is provided a signal amplifier using a conventional Doherty amplifier.

As shown in FIG. 1, the signal amplifier includes a splitter 1, a transmission line 2, a Doherty amplifier 3, a first load line 4 and a second load line 5. The Doherty amplifier 3 has a carrier amplifier 6 and a peaking amplifier 7. Further, the carrier amplifier 6 includes an input matching circuit 8 and a transistor 9; and the peaking amplifier 7 similarly includes an input matching circuit 8′ and a transistor 9′.

In the conventional Doherty amplifier, an input signal is split into two signals at the splitter 1 and inputted into the Doherty amplifier 3. One of the two signals is fed to the carrier amplifier 6 and the other signal is delayed by the transmission line 2 having characteristic impedance Zₐ and then fed to the peaking amplifier 7. The delay of the signal may be adjusted so that an output of the peaking amplifier 7 lags with respect to an output of the carrier amplifier 6 by 90 degrees.

Each of the respective transistors 9 and 9′ of the carrier amplifier 6 and the peaking amplifier 7 is fed with a predetermined base bias voltage regardless of the power level of the input signal. The peaking amplifier 7 is driven by the base bias voltage and provides a current to the second load line 5 in accordance with the power level of the input signal. As the amount of the current supplied to the second load line 5 varies, an impedance of the first load line 4 connected an output port of the carrier amplifier 6 is adjusted to thereby control the efficiency of the Doherty amplifier 3. Two quarter-wave transmission lines having characteristic impedances Zₘ and Z_{b} may be used for the first and second load lines 4 and 5 connected to respective output ports of the carrier amplifier 6 and the peaking amplifier 7, respectively.

Then, the signals transmitted respectively from the first load line 4 and the peaking amplifier 7 are combined at a combination circuit common node to be outputted through the second load line 5.

This structure of Doherty amplifier can perform a matching of an imaginary part as well as a real part of the impedances so that an output power of the amplifier is maximized.

However, though the prior Doherty amplifier achieves higher efficiency and more output power in comparison to a class AB amplifier while maintaining a same level of linearity, it is insufficient to achieve an improvement in linearity needed to accomplish high capability and functionality of an amplifier.

The present invention introduces an adaptive bias control to the Doherty amplifier for further improvement in efficiency and linearity.

### SUMMARY OF THE INVENTION

It is, therefore, an object of the present invention to provide a Doherty amplifier for detecting and transforming an envelope voltage of an input signal and for applying it to control a carrier amplifier and a peaking amplifier so that efficiency thereof is maximized while improving its linearity to a desired level.

In accordance with a preferred embodiment of the present invention, there is provided an amplifier circuit comprising: a coupler for splitting an input signal; an envelope detector for detecting an envelope signal from one part of the input signal; a plurality of envelope shaping circuits for performing a shaping of the envelope of the input signal; and a Doherty amplifier for amplifying the other part of the input signal in accordance with the shaped envelope signal from the envelope shaping circuits, wherein the Doherty amplifier includes an input network, a carrier amplifier, a plurality of peaking amplifiers and an output network.

### BRIEF DESCRIPTION OF THE DRAWINGS

The above and other objects and features of the present invention will become apparent from the following description of preferred embodiments given in conjunction with the accompanying drawings, in which:

FIG. 1 illustrates a prior Doherty amplifier;

FIG. 2 describes a Doherty amplifier using adaptive bias control in accordance with the present invention;

FIG. 3A offers a graph for showing a control of gate and drain bias voltages of the Doherty amplifier of FIG. 2;

FIG. 3B provides a change of load line of the carrier amplifier for the Doherty amplifier of FIG. 2;

FIG. 4A illustrates an envelope voltage of a specific input signal for the Doherty amplifier of FIG. 2;

FIG. 4B depicts a shape of drain voltage of the carrier amplifier adaptive controlled in accordance with the envelope voltage of FIG. 4A; and

FIG. 5 sets forth a comparison of an output efficiency of a conventional class AB amplifier and the Doherty amplifier of FIG. 2.

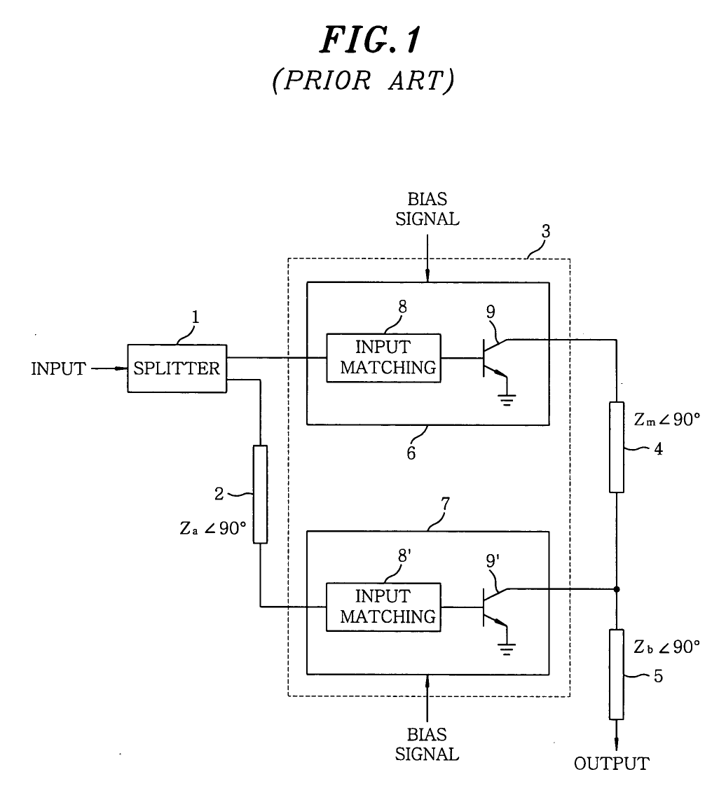

### DETAILED DESCRIPTION OF THE PREFERRED EMBODIMENTS

The preferred embodiment of the present invention will now be described in detail with reference to the accompanying drawings.

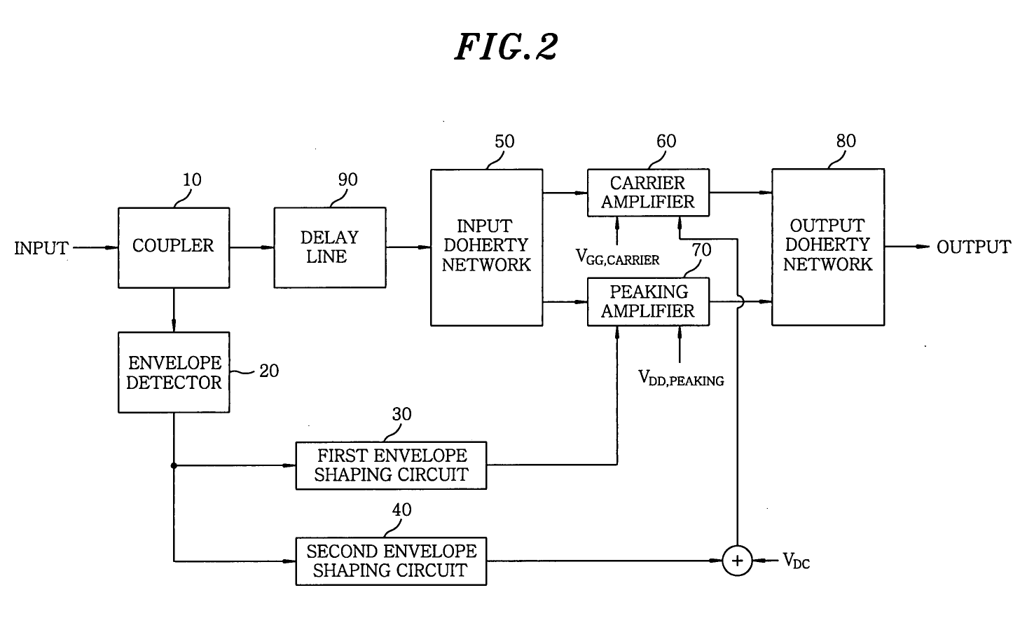

FIG. 2 shows a preferred embodiment of the present invention, wherein an extremely high frequency Doherty amplifier using an adaptive bias control includes a coupler 10, an envelope detector 20, a first envelope shaping circuit 30, a second envelope shaping circuit 40, an input Doherty network 50, a carrier amplifier 60, a peaking amplifier 70, an output Doherty network 80 and a delay line 90.

A part of the input signal for the Doherty amplifier is extracted by the coupler 10 and is provided into the envelope detector 20. The rest of the input signal is provided to the input Doherty network 50 through the delay line 90.

The envelope detector 20 detects an envelope voltage of the input signal. An envelope voltage is provided to each of the first envelope shaping circuit 30 and the second envelope shaping circuit 40.

The first envelope shaping circuit 30 transforms the envelope voltage and applies a transformed envelope voltage to the peaking amplifier 70 as a gate bias voltage to control a gate bias of the peaking amplifier 70.

The second envelope shaping circuit 40 transforms the envelope voltage. And then, V_{DC} is added to an output of the second envelope shaping circuit 40 and an added result is applied to the carrier amplifier 60 as a drain bias voltage to control a drain bias of the carrier amplifier 60. The V_{DC} is set as an appropriate level of direct current voltage for biasing the drain of the carrier amplifier 60.

The carrier amplifier 60 is operated under the control of a gate bias voltage directly supplied from a power supply and the drain bias voltage from the second envelope shaping circuit 40, and amplifies the input signal provided from the input Doherty network 50 to provide an amplified signal to the output Doherty network 80.

The peaking amplifier 70 is operated under the control of a drain bias voltage directly supplied from a power supply and the gate bias voltage from the first envelope shaping circuit 30, and amplifies the input signal provided from the input Doherty network 50 to provide another amplified signal to the output Doherty network 80.

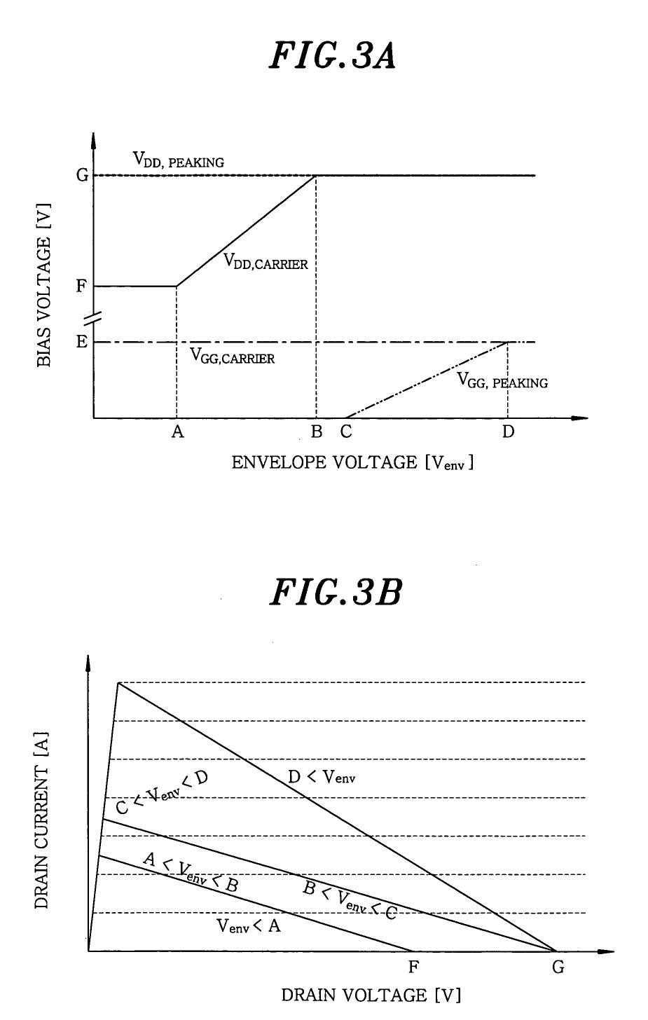

FIG. 3A shows a gate and a drain bias control scheme of the Doherty amplifier in accordance with the present invention.

When the envelope voltage of the input signal provided from the envelope detector 20 is below C level, the peaking amplifier 70 is in “OFF” state and only the carrier amplifier 60 is being operated. After the envelope voltage reaches to C level, the peaking amplifier 70 turns to be in “ON” state slowly and as the envelope voltage reaches to D level, the gate bias voltage of the peaking amplifier 70 gets to be equal with that of the carrier amplifier 60.

The respective drain bias voltages of the carrier amplifier 60 and the peaking amplifier 70 are set to be uniform at G value after the envelope voltage gets to be higher than B value. The output power at C value is lower than that at D value by about 6 dB.

Since the carrier amplifier 60 is saturated after the envelope voltage is increased beyond C value, it is preferable to keep the drain bias of the carrier amplifier 60 below C value for keeping its linearity at a desired level. That is, high drain voltage is required in order to obtain high linearity.

And further, since a gate voltage of the peaking amplifier 70 is way below C value such that the peaking amplifier 70 is turned off, only the carrier amplifier 60 is available to be controlled in that range. In other words, the drain voltage of the carrier amplifier 60 is sustained in a comparatively low level (F value) while the envelope voltage is below A value. The drain voltage of the carrier amplifier 60 increases in due time after the envelope voltage is increased beyond A value, and is comparatively a high level (G value) when the envelope voltage reaches B value.

FIG. 3B shows a variation of load line for the carrier amplifier in accordance with the Doherty control scheme illustrated in FIG. 3A. When the envelope voltage is increased beyond D value, the amplifier is operated with an equal load line impedance which is equal to that of a general class AB amplifier. And the load line impedance increases continuously until the envelope voltage reaches to C value and the load line impedance of C value becomes two times as large as that of D value. And also, the load line moves in parallel by the control of the drain bias of the carrier amplifier 60 between A value and B value.

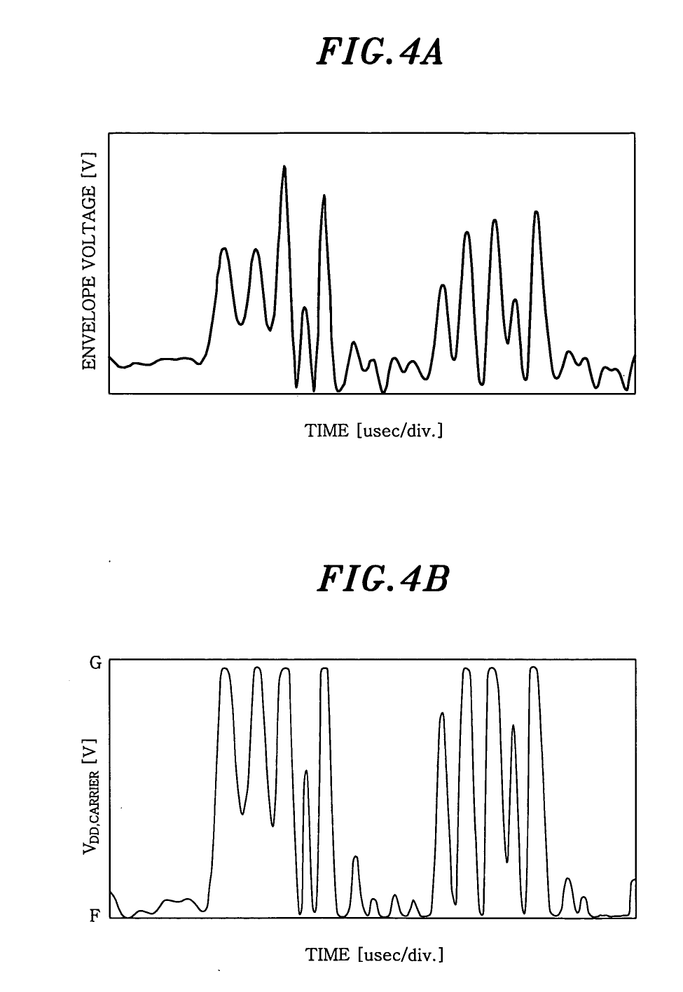

FIG. 4A shows an envelope voltage of an exemplar of the input signal of the Doherty amplifier of FIG. 2, while FIG. 4B shows a drain voltage of the carrier amplifier 60 when the envelope voltage of FIG. 4A is applied to the Doherty amplifier of FIG. 2. By comparing FIG. 4A with FIG. 4B, when the envelope of the input signal is high, the drain bias voltage of the carrier amplifier becomes also to be high at the same time.

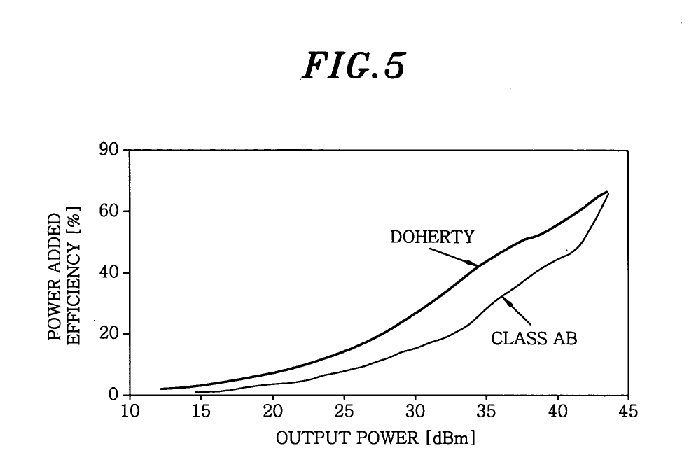

FIG. 5 shows a result of a test under a condition that the adaptive bias control scheme of FIG. 3A is applied to the Doherty amplifier in accordance with the present invention. By selecting an operating point among A to G values of FIG. 3A for the envelope voltage and the bias voltage, a linearity and an efficiency can be maximized. As shown in FIG. 5, power added efficiency (PAE) of the Doherty amplifier is greater than that of a conventional class AB amplifier when continuous wave is applied to both of them.

In another embodiment of the present invention, a plurality of envelope shaping circuits may be used for improvement of output efficiency. An output of the envelope detector is split into plural ways and an envelope shaping circuit and a peaking amplifier are provided in each way. The output of the envelope detector is supplied to a corresponding envelope shaping circuit and transformed into an appropriate signal form. An output signal of each envelope shaping circuit is applied to a corresponding carrier amplifier and each peaking amplifier to thereby control them.

In another embodiment of the present invention, outputs of envelope shaping circuits may be provided to a carrier amplifier and plural peaking amplifiers, wherein the outputs of the envelope shaping circuits may be used for control of gate or drain voltage of each amplifier, or drain voltage for the peaking amplifier and gate voltage for the carrier amplifier.

In still another embodiment of the present invention, each of the plural peaking amplifiers can be disposed in parallel or in cascade for forming a multi-way amplifier or a multi-stage amplifier, respectively. In this embodiment, the envelope shaping circuits may be coupled to the amplifier.

As described above, the Doherty amplifier in accordance with the present invention controls bias voltage of the carrier amplifier and the peaking amplifier by transforming of envelope signals to increase an output power thereof and therefore achieves high linearity and efficiency at the same time.

While the invention has been shown and described with respect to the preferred embodiments, it will be understood by those skilled in the art that various changes and modifications may be made without departing from the spirit and scope of the invention as defined in the following claims.

What is claimed is:

1. A Doherty amplifier comprising:
a coupler for splitting an input signal;
an envelope detector for detecting an envelop voltage from one part of the input signal;
a plurality of envelope shaping circuits for transforming the envelope voltage of the input signal; and
a plurality of amplifiers for amplifying the other part of the input signal under control of the transformed envelope voltage provided from the envelope shaping circuits.

2. The Doherty amplifier of claim 1, wherein one of the plurality of amplifiers functions as a carrier amplifier and the other amplifiers function as peaking amplifiers.

3. The Doherty amplifier of claim 2, wherein one of the pluralities of envelope shaping circuits is coupled to the carrier amplifier and the other envelope shaping circuits are coupled to the peaking circuits.

4. The Doherty amplifier of claim 3, wherein a transformed envelope signal from one envelope shaping circuit is added with V_{DC} and applied to the carrier amplifier as a drain bias signal and other shaped envelope signals from the rest of the envelope shaping circuits are applied to the plurality of peaking amplifiers as a gate bias signal.

5. The Doherty amplifier of claim 3, wherein the shaped envelope signal from one envelope shaping circuit is applied to the carrier amplifier as a gate bias signal and other shaped envelope signals from the rest of the envelope shaping circuits are added with V_{DC} and applied to the plurality of peaking amplifiers a drain bias signal.

6. The Doherty amplifier of claim 1 further comprising an input matching network and an output matching network, the input matching network being disposed between the coupler and input part of the amplifiers and the output matching network being disposed at output part of the amplifiers.

7. The Doherty amplifier of claim 5, wherein the input matching network and the output matching network include quarter-wave transformer lines.

8. The Doherty amplifier of claim 2, wherein each of the plurality of the peaking amplifiers connected in cascade is coupled to the corresponding envelope shaping circuit for providing bias signal.

9. The Doherty amplifier of claim 2, wherein each of the plurality of the peaking amplifiers connected in parallel is coupled to the corresponding envelope shaping circuit for providing bias signal.

10. A Doherty amplifier using an adaptive bias control, comprising:
a coupler for splitting an input signal;
a delay line for transferring one part of the input signal;
an envelope detector for detecting envelope voltage as an envelope signal from the other part of the input signal;
a first envelope shaping circuit for transforming the envelope signal from the envelope detector and applying the transformed envelope signal as a gate control bias voltage to a corresponding amplifier;
a second envelope shaping circuit for transforming of the envelope signal from the envelope detector and applying a drain control bias voltage to corresponding amplifier, the drain control bias voltage is the transformed envelope signal and V_{DC};
a carrier amplifier for amplifying the other part of the input signal, the carrier amplifier being controlled by the drain bias voltage from the second envelope shaping circuit;
a peaking amplifier for amplifying the other part of the input signal, the peaking amplifier being controlled by the gate bias voltage from the first envelope shaping circuit;
an input matching network disposed between the delay line and the carrier and peaking amplifiers for input impedance matching; and
an output matching network coupled to the outputs of the carrier and peaking amplifiers so as to combine the outputs of the amplifiers.
